(19) United States
(12) Patent Application Publication
(10) Pub. No.: US 2024/0250211 A1
(43) Pub. Date: Jul. 25, 2024

(54) Regrowth Structures for Micro LED

(71) Applicant: Apple Inc., Cupertino, CA (US)

(72) Inventors: Erin C. Young, Mountain View, CA (US); Ling Zhang, Saratoga, CA (US); David P. Bour, Cupertino, CA (US)

(21) Appl. No.: 18/408,246

(22) Filed: Jan. 9, 2024

Related U.S. Application Data
(60) Provisional application No. 63/481,233, filed on Jan. 24, 2023.

(51) Int. Cl. H01L 33/24; H01L 25/075; H01L 33/00; H01L 33/30

(52) U.S. Cl. CPC H01L 33/24; H01L 25/0753; H01L 33/0062; H01L 33/305

(57) ABSTRACT

Light emitting diodes with regrown semiconductor layers and methods of manufacture are described. In an embodiment, a light emitting diode includes a base structure including a first cladding layer doped with a first dopant type (e.g. n-type) and step surface. A mesa pillar including an active layer protrudes from the step surface, and a regrown second cladding layer doped with a second dopant type (e.g. p-type) is in direct contact with and spans a bottom surface and sidewalls of the mesa pillar and the step surface.

### RELATED APPLICATIONS

This application claims the benefit of priority of U.S. Provisional Application No. 63/481,233 filed Jan. 24, 2023, which is incorporated herein by reference.

### BACKGROUND

### Field

Embodiments described herein relate to light emitting diodes (LEDs). More particularly embodiments relate to LED regrowth structures.

### BACKGROUND INFORMATION

State of the art displays for electronic devices such as wearable devices, portable electronics, desktop computers, and televisions are based on liquid crystal display (LCD) or organic light emitting diodes (OLED) technologies. More recently, it has been proposed to incorporate emissive inorganic semiconductor-based micro LEDs based on III-V or II-VI systems into high resolution displays, with the potential for energy efficiency and being less prone to lifetime degradation and sensitivity to moisture. Generally, a vertical inorganic semiconductor-based micro LED may include a p-doped hole injection layer, an n-doped electron injection layer, and an active layer between the hole injection layer and electron injection layer. The active layer may include one or more quantum well layers and barrier layers for example. In operation light is emitted as a result of recombination of holes and electrons in the quantum wells. It has been observed however that surface defect states created at micro LED sidewalls, and more particularly sidewalls of the active layer, can lead to nonradiative recombination of holes and electrons, and hence a reduction in internal quantum efficiency (IQE) of the micro LEDs. In order to address these defect states, it has been proposed to passivate the etched mesa surface using a variety of techniques such as diffusion or regrowth. In a specific implementation described in U.S. Pat. No. 9,484,492 a semiconductor passivation layer is re-grown following etching of a p-n diode mesa structure to preserve the lattice structure.

### SUMMARY

LED structures and methods of manufacture are described in which a regrown semiconductor layer is utilized to passivate the sidewalls of a patterned mesa pillar that includes an active layer of the LED. The mesa pillar structure in accordance with embodiments can be formed using etching techniques that can be performed in a chamber separate from the reaction chamber used for semiconductor layer regrowth, or in situ in the reaction chamber. In some embodiments multiple etching operations are performed, inclusive of a bulk etch followed by in situ etch and regrowth. Furthermore, various cleaning operations may be performed to remove contamination such as oxides prior to regrowth.

### BRIEF DESCRIPTION OF THE DRAWINGS

FIGS. 1A-1H are schematic cross-sectional side view illustrations of a sequence for forming an array of micro LEDs with regrown semiconductor passivation layers on a carrier substrate in accordance with an embodiment.

FIG. 2 is a schematic cross-sectional side view illustration of a micro LED with regrown semiconductor passivation layers bonded on a display substrate in accordance with an embodiment.

FIGS. 3A-3H are schematic cross-sectional side view illustrations of a sequence for forming an array of micro LEDs with regrown cladding layers on a carrier substrate in accordance with an embodiment.

FIG. 4 is a schematic cross-sectional side view illustration of a micro LED with a regrown cladding layer bonded on a display substrate in accordance with an embodiment.

FIGS. 5A-5J are schematic cross-sectional side view illustrations of a sequence for forming an array of micro LEDs with a regrown cladding layer on a carrier substrate in accordance with an embodiment.

FIG. 6 is a schematic cross-sectional side view illustration of a micro LED with a regrown cladding layer bonded on a display substrate in accordance with an embodiment.

FIG. 7 is a plan view illustration of an MOCVD system in accordance with embodiments.

FIG. 8 is a flow chart illustration for an in situ sequence of operations during the formation of an array of micro LEDs in accordance with an embodiment.

### DETAILED DESCRIPTION

Embodiments describe LED structures and methods of manufacture in which a mesa pillar structure is patterned to define the width of an active layer, followed by regrowth of a semiconductor layer around the mesa pillar to passivate the surface and mitigate defects that can contribute to non-radiative recombination. In some embodiments, the regrown semiconductor layer can be a passivation layer similar to a doped cladding layer for charge injection to the active layer. In other embodiments, the regrown semiconductor layer is a doped cladding layer for charge injection to the active layer.

In accordance with embodiments various cleaning or surface conditioning operations may be formed prior to regrowth or etching in order to remove impurities, such as oxide formation due to exposure of aluminum containing layers to ambient, and in particular layer with high aluminum concentration. Additionally, various etching sequences are described including single and multiple etching operation to form the mesa pillar, as well as combinations of cleaning and/or etching operations performed ex situ and in situ with regrowth.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

In some embodiments, the term “micro” LED as used herein may refer to the descriptive size, e.g. length or width, of the LED. In some embodiments, “micro” LEDs may be on the scale of 0.1 μm to approximately 100 μm or less in many applications. More specifically, in some embodiments, “micro” LEDs may be on the scale of 0.1 μm to 20 μm, such as 10 μm, 5 μm, 3 μm, or 1 μm where the LED lateral dimensions approach or surpass the carrier diffusion length. However, it is to be appreciated that embodiments are not necessarily so limited, and that certain aspects of the embodiments may be applicable to larger, and possibly smaller size scales.

In the following description exemplary processing sequences and structures are described for forming LEDs, and in particular micro LEDs. While specific arrangements layers with specific dopant types are described, it is to be appreciated that polarity may be reversed. For example, the relative orientation of p-type or n-type layers or dopant types can be reversed. Additionally reference to an opposite dopant type refers to p-dopant or opposite n-dopant as is common in semiconductor fabrication to achieve primary hole or opposite electron transfer through a semiconductor layer.

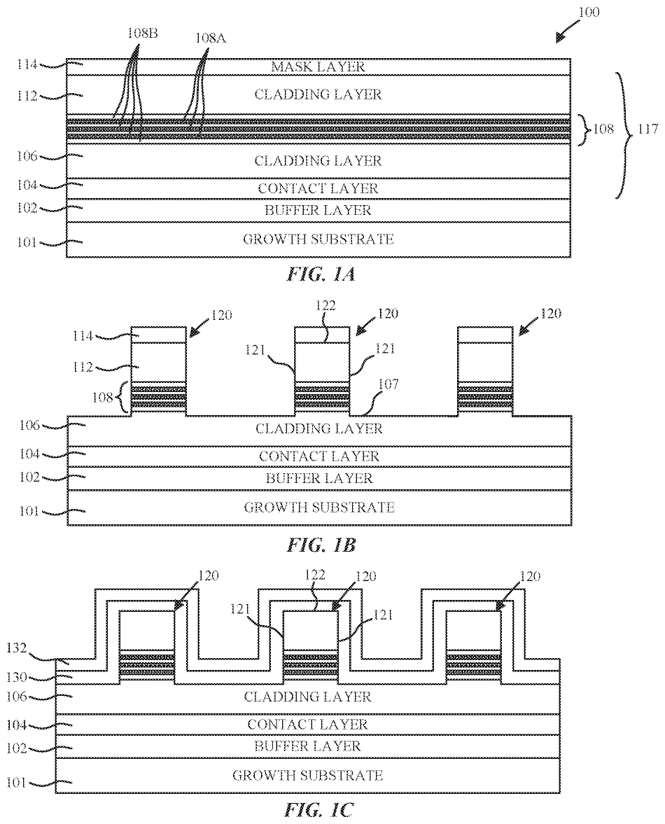

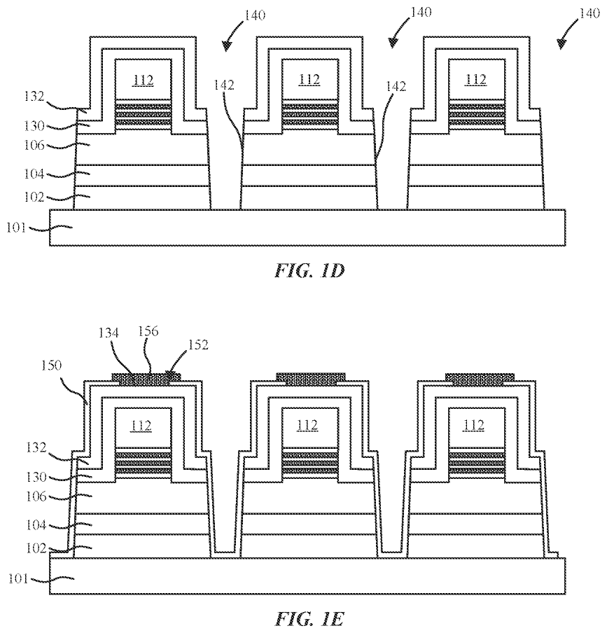

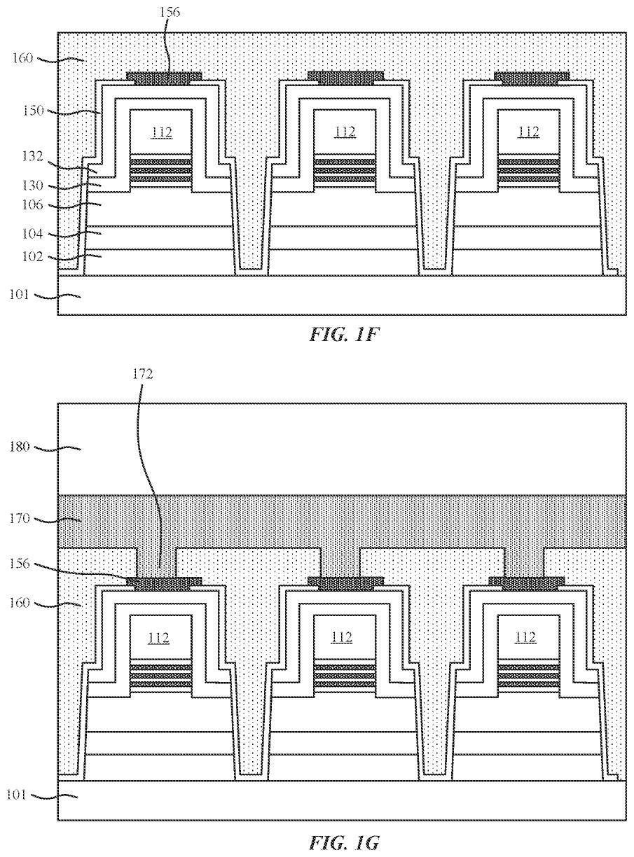

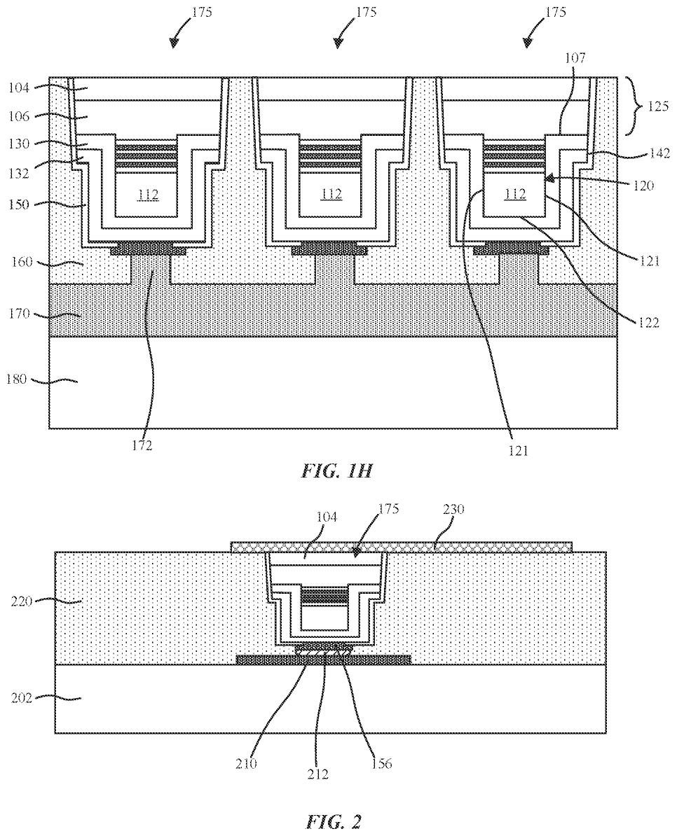

Referring now to FIG. 1A, a cross-sectional side view illustration is provided of a bulk LED substrate 100 in accordance with an embodiment. The bulk LED substrate 100 structure may be applicable to a variety of compositions and emission spectra. For example, the bulk LED substrate 100 may include III-V nitride materials or III-V phosphide materials and designed for emission of a variety of emission spectra. In a specific embodiment, the bulk LED substrate 100 is based on an AlInGaP material system and is designed for red color emission. For example, bulk LED substrate 100 may be designed for a peak emission wavelength between 600 nm-750 nm, such as 625 nm. While the following structures are described with regard to an AlInGaP material system, the exemplary structures and concepts may be used for LEDs and electronic devices based on alternative material systems such as group-III-V arsenide materials.

In one embodiment, formation of the bulk LED substrate 100 begins with the formation of a device layer 117 on a growth substrate 101, such as a GaAs growth substrate, for example with a thickness of 250-1,000 μm. Growth substrate 101 may optionally be doped, for example with an n-type dopant such as silicon (Si) or tellurium (Te). The multiple layers of the device layer 117 may be grown on the growth substrate 101 using a suitable technique such as metal organic chemical vapor deposition (MOCVD). In order to mitigate lattice mismatch a buffer layer 102 may first be formed on the growth substrate 101. The buffer layer 102 may include one or more layers. In an exemplary embodiment the buffer layer includes a graded layer. The graded buffer layer 102 for example may be graded from GaAs to AlₓGa₍₁₋ₓ₎As with increasing Al concentration, and may also be doped, for example with an n-type dopant. In an embodiment, buffer layer 102 is graded with an Al concentration of x=0 to x=0.8, and may have a thickness of 150-800 nm. The buffer layer may additionally include non-graded layers.

Following formation of the buffer layer 102 a top contact layer 104 (e.g. n-type contact layer) may be grown. For example, the top contact layer 104 may be (AlₓGa₁₋ₓ)_{0.5}In_{0.5}P, with 0.2≤x≤0.8, such as 0.5≤x≤0.8, and a Si or Te n-type dopant concentration of 0.5-4×10¹⁸ cm⁻³. The top contact layer 104 may have an exemplary thickness of 100 nm, sufficient to spread charge. A first cladding layer 106 (e.g. n-type cladding layer) is then formed over the optional top contact layer 104, for example to a thickness of 0.05-0.9 μm. First cladding layer 106 may be formed of materials such as AlInP, AlGalnP, and AlGaAs. In an embodiment, first cladding layer 106 is formed of AlInP with a Si dopant concentration of 1×10¹⁸ cm⁻³.

An active layer 108 is then grown on the first cladding layer 106. Active layer 108 may include one or more quantum well (QW) layers or bulk active layers. In an embodiment the one or more quantum well layers 108A or bulk active layers are formed of AlGaAs, InGaP or AlInGaP, separated by barrier layers 108B formed of a material with a large conduction band offset with respect to the one or more quantum well layers in the active layer 108. In this aspect, a maximum conduction band offset to the quantum wells confines electrons to the quantum wells.

A second cladding layer 112 may then be formed over the active layer 108. The second cladding layer 112 (e.g. p-type cladding layer) may be formed of materials such as AlInP, AlGalnP, and AlGaAs. In an embodiment, second cladding layer 112 is formed of AlInP with a Mg dopant concentration of 5×10¹⁷ cm⁻³-1.5×10¹⁸ cm⁻³, such as 1×10¹⁸ cm⁻³. In accordance with embodiments, the doped cladding layers 104, 112 may be selected to have a high band gap in order to confine the injected carriers. For example, the doped cladding layers 106, 112 may have a higher bandgap energy than the barrier layers 108B. In an embodiment, the barrier layers 108B are (AlₓGa₁₋ₓ)_{0.5}In_{0.5}P alloys with 0.2≤x≤0.8, such as 0.5≤x≤0.8. In an embodiment, the doped cladding layers 106, 112 are (AlₓGa₁₋ₓ)_{0.5}In_{0.5}P alloys with 0.6≤x≤1.0.

In an embodiment, the second cladding layer 112 may have a substantially uniform p-dopant concentration, less a concentration gradient due to diffusion with the surrounding layers. In an embodiment, the p-dopant concentration is not uniform. For example, doping may begin after a specific set back distance, such as 100-200 nm into the p-type cladding layer 112. A mask layer 114 can then be formed over the second cladding layer 112. The mask layer 114 may include one or more layers. In an embodiment, the mask layer includes an oxide layer such as SiO₂.

It is to be appreciated that the specific layer stack up is exemplary and embodiments are not so limited. Additional layers such as confinement layers, etc. may be included for various reasons, and some layers may be optionally removed.

Referring now to FIG. 1B, the mask layer 114 can be patterned into a plurality of islands followed by etching the second cladding layer 112 and active layer 108, and optionally partially into the first cladding layer 106 to form a plurality of mesa pillars 120. The etched mesa pillars 120 may be characterized by mesa sidewalls 121, a bottom surface 122 of the second cladding layer 112, and a step surface 107 of the first cladding layer 106. Etching can be followed by stripping of the patterned mask layer 114, for example with a vapor hydrofluoric acid (HF) etch or buffered oxide etch (BOE), and regrowth of semiconductor passivation layer 130 of the second dopant type (e.g. p-type) and one or more contact layers 132 (e.g. p-type) as shown in FIG. 1C. As shown in FIG. 1C, the regrown semiconductor passivation layer 130 is formed along the mesa sidewalls 121 and top surface 122 of the mesa pillar 120 and top surface of the first cladding layer 106. For example, the semiconductor passivation layer 130 may be formed of the same material as the second cladding layer 112. The contact layer 132 may be formed of GaP, GaAs or AlGaAs, for example, with a with a Mg, Zn, or C p-type dopant concentration of 1×10¹⁸ cm⁻³-1×10¹⁹ cm⁻³. In an embodiment, the semiconductor passivation layer 130 has the same stoichiometric composition as the second cladding layer 112.

In an embodiment, the mesa pillars 120 may be etched in an ex situ process in which the etching of the mesa pillars 120 is performed using a dry etching technique such as deep reactive ion etching (DRIE) followed by cleaning, and transfer to a Metal-Organic Chemical Vapor Deposition (MOCVD) system for regrowth. Cleaning can also be performed after transfer to the MOCVD system.

In one aspect, it has been observed that unintentional impurity concentrations such as oxygen can exist at the interface between the regrown semiconductor passivation layer 130 and the underlying topography including the mesa sidewalls 121 and top surface 122 of the mesa pillar 120 and top surface 107 of the first cladding layer 106. It has been observed that a particular source of oxygen contamination is exposure to aluminum containing layers to ambient atmosphere, for example after etchings. Impurities (including oxide contamination) along mesa sidewalls 121, and in particular near the active layer 108, can themselves be nonradiative impurities that subtract from the radiative efficiency of the micro LED, and also destroy the crystal quality of the regrown layer resulting in structural defects that represent another form of nonradiative site. Oxide contamination along the first confinement layer 106 (e.g. n-type confinement layer) step surface 107 can also form a parasitic p-n junction that shunts current around the core of the micro LED. Furthermore, contamination of other impurities such as silicon or carbon along the top surface 122 of the mesa pillar 120 can render the material n-type, creating a p-n-p interface that blocks current injection into the core of the micro LED. In accordance with various embodiments, cleaning and in situ processes may mitigate various sources of contamination.

In an embodiment, an aqueous HF clean is performed prior to regrowth to remove surface oxides. The substrate is then transferred to the MOCVD system after cleaning for regrowth of the semiconductor passivation layer 130.

In an embodiment, a hydrogen clean is performed prior to regrowth of the semiconductor passivation layer 130. For example, a hydrogen plasma source can be connected to the MOCVD system so that cleaning is performed within the MOCVD system and regrowth can immediately follow cleaning without need of additional handling and transfer.

In yet another embodiment etching of the mesa pillars 120 is performed in situ inside the reaction chamber of the MOCVD system immediately before regrowth of the semiconductor passivation layer 130. In such an embodiment various chlorine containing corrosive precursors can be used for etching including tertiarybutylchloride (TBCI), phosphorous trichloride (PCl₃), Cl₂, and hydrogen chloride (HCl) so as to not introduce additional oxygen contamination by exposure to ambient atmosphere outside of the MOCVD system.

Referring now to FIG. 1D, upon completion of the regrowth sequence, trenches 140 can be etched through the underlying structure using a suitable technique such as DRIE. The trenches 140 and edge sidewalls 142 formed by the trenches 140 may span through multiple layers including the bottom contact layer(s) 132 (e.g. p-type contact layer(s)), semiconductor passivation layer 130, first cladding layer 104, and top contact layer (e.g. n-type contact layer). The trenches 140 and edge sidewalls 142 may additionally extend into, or completely through, the buffer layer(s) 102. In the illustrated embodiment, the trenches 140 are formed to the growth substrate 101, though this is not required, and the trenches 140 need not extend all the way to the growth substrate 101. As will become apparent in the following description, the edge sidewalls 142 will become edge sidewalls of for each micro LED.

Following formation of trenches 140, an insulation layer 150 can be formed, for example using a conformal deposition or growth technique such as atomic layer deposition. In an embodiment the insulation layer is formed of a material such as aluminum oxide, though other materials may be used. In an embodiment, insulation layer 150 is between 0-1,000 nm thick, such as 1-100 nm thick, and may have a uniform thickness that conforms to the underlying substrate topography and forms an outline. The insulation layer 150 may then be patterned to form openings 152 over the mesa pillars 120 that expose the bottom contact layer 132. For example, this may be accomplished using a fluorine based dry etching technique. Bottom conductive contacts 156 may then be formed on the exposed portions 134 of the bottom contact layer 132 within openings 152 as illustrated in FIG. 1D. Conductive contacts 156 may include a multiple layer stack, such as multiple metal/metallic layers. Exemplary layers can include electrode layers, mirror layers, adhesion/barrier layers, diffusion barriers, and a bonding layer for bonding the completed LEDs to a receiving substrate.

Referring now to FIG. 1F, a sacrificial release layer 160 may be formed over the underlying topography and then patterned to form openings over the conductive contacts 156. The sacrificial release layer 160 may be formed of an oxide (e.g. SiO₂) or nitride (e.g. SiNₓ), though other materials may be used which can be selectively removed with respect to the other layers. The height, width, and length of the openings will correspond to the height, length, and width of the stabilization posts to be formed, and resultantly the adhesion strength that must be overcome to pick up the array of LEDs (e.g. micro LEDs) that are poised for pick up on the array of stabilization posts.

The patterned structure on the growth substrate 101 can then be bonded to a carrier substrate 180 with an adhesive bonding material to form stabilization layer 170 as shown in FIG. 1G. In an embodiment, the adhesive bonding material is a thermosetting material such as benzocyclobutene (BCB) or epoxy. The portion of the stabilization material that fills openings corresponds to the stabilization posts 172 of the stabilization layer 170. Any portion of the stabilization layer 170 that may fill the trenches 140 (e.g. where the sacrificial release layer 160 is conformal, and thinner than illustrated) can further provide a stabilization cavity.

After bonding to the carrier substrate 180, the growth substrate 101 may be removed utilizing a suitable technique such as laser lift-off, etching, etc. Furthermore, the buffer layer 102 may also be removed to expose the top contact layers 104 to form laterally separate LEDs 175 (micro LEDs).

In an embodiment, an LED 175 includes a base structure 125 which includes a first cladding layer 106 doped with a first dopant type (e.g. top, n-type cladding layer 106) and a step surface 107. The base structure 125 may additionally include a top contact layer 104 (e.g. n-type contact layer). As shown, a mesa pillar 120 protrudes from the step surface 107 of the base structure 125 and includes an active layer 108. In the particular embodiment illustrated the active layer 108 includes a plurality of quantum well layers 108A and barrier layers 108B. The mesa pillar additionally includes a second cladding layer 112 (e.g. p-type cladding layer). A regrowth structure may be formed around the mesa pillar 120 and along the step surface 107. As shown, a semiconductor passivation layer 130 (e.g. p-type semiconductor passivation layer) can be in direct contact with and span the bottom surface 122 and mesa sidewalls 121 of the mesa pillar 120 as well as the step surface 107 of the base structure 125. Thus, the semiconductor passivation layer can wrap underneath the mesa pillar and step surface. Additionally, a bottom contact layer 132 (e.g. p-type contact layer) may be formed directly on the semiconductor passivation layer and wrap underneath the semiconductor passivation layer.

In accordance with the illustrated embodiment the LED 175 sidewalls may be composed of the edge sidewalls 142 that span across the (etched) bottom contact layer 132, semiconductor passivation layer 130, the first cladding layer 106, and optional top contact layer 104. The LED sidewalls may additionally be composed of the optional bottom contact layer 132 that wraps underneath the semiconductor passivation layer and the mesa pillar 120.

FIG. 2 is a schematic cross-sectional side view illustration of an LED 175 (micro LED) with regrown semiconductor passivation layer bonded on a display substrate 202 in accordance with an embodiment. In accordance with embodiments, the LED 175 array of FIG. 1H can be processed to remove the sacrificial release layer 160, such as with a vapor HF etch process, followed by transfer to a receiving substrate such as display substrate 202. Transfer may be achieved with an array of transfer heads. Multiple arrays of micro LEDs 175 designed for different color emissions may be transferred to the display substrate. As shown, a bonding pad 210 can be formed on the display substrate 202. For example, the bonding pad 210 may be connected to driving circuitry within the display substrate 202. The LED 175 may be bonded to the bonding pad 210 with a bonding material 212 such as a solder material that bonds the bottom conductive contact 156 to the bonding pad 210. The LED 175, and for that matter a plurality or array of LEDs, can be encapsulated within an insulation material 220, such as a polymer material. The insulation material may additionally function to hold the micro LED in place and provide step coverage for the formation of a top electrode layer 230, such as a transparent conductive oxide (TCO) or transparent polymer material to provide electrical connection to the top side of the LED 175. The top electrode layer 230 may be formed directly on the top contact layer 104 or an intermediate layer.

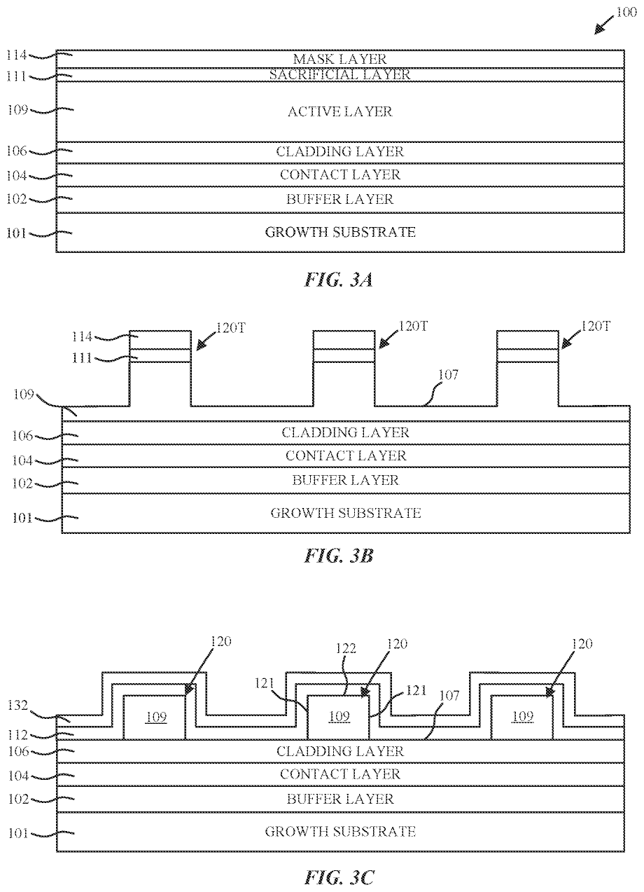

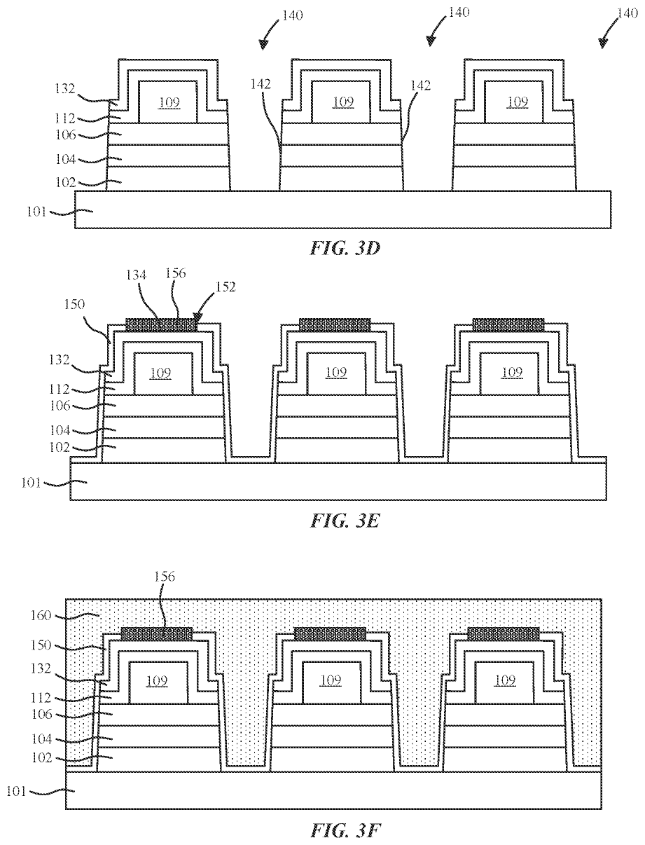

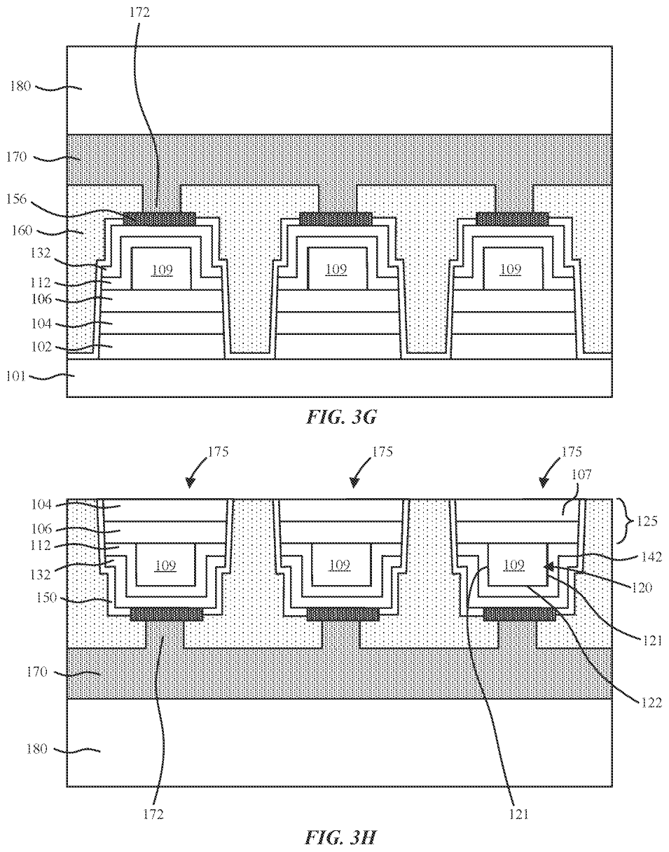

Referring now to FIGS. 3A-3H schematic cross-sectional side view illustrations are provided of a sequence for forming an array of micro LEDs with regrown cladding layers on a carrier substrate in accordance with an embodiment. It is to be appreciated that the various structures presented in FIGS. 3A-3H may share similar layers and compositions as the layers previously described and illustrated with regard to FIGS. 1A-1H. Accordingly, in the interest of clarity and conciseness, the description of layers and structures with similar arrangements and compositions may not be repeated.

As shown, the process sequence may begin with a bulk LED substrate 100 including a growth substrate 101 (e.g. GaAs), one or more buffer layers 102 (e.g. graded from GaAs to AlGaAs), a top contact layer 104 (e.g. n-type contact layer) such as (AlₓGa₁₋ₓ)_{0.5}In_{0.5}P, with 0.2≤x≤0.8, a first cladding layer 106 (e.g. n-type cladding layer) such as (AlₓGa₁₋ₓ)_{0.5}In_{0.5}P alloys with 0.6≤x≤1.0, in particular AlInP, an active layer 109 such as (AlₓGa₁₋ₓ)_{0.5}In_{0.5}P, with 0.2≤x, a sacrificial semiconductor layer 111, such as (AlₓGa₁₋ₓ)_{0.5}In_{0.5}P, with x=0, and a mask layer 114 as previously described.

Referring now to FIGS. 3B-3C, a two-part etching sequence may be performed to form the mesa pillars 120. In accordance with embodiments, the mesa pillar templates 120T can first be formed using an etching technique such as DRIE to etch through the sacrificial semiconductor layer 111 and a bulk of the active layer 109 using a patterned mask layer 114. This is a bulk etching operation used to create a template for the mesa pillars to be formed. This etching operation may be formed completely through the sacrificial semiconductor layer 111 and partially through a thickness of the active layer 109 as shown in FIG. 3B. Following the bulk etching operation the substrate stack can then be transferred to a reaction chamber such as MOCVD reaction chamber where a second etching in situ etching operation is performed to etch completely through the active layer 109 to form the mesa pillars 120, which may expose the first cladding layer 106 (or other intervening layer). Such an etching operation may etch partially through a thickness of the first cladding layer 106. In such an embodiment various chlorine containing corrosive precursors can be used for etching including tertiarybutylchloride (TBCI), phosphorous trichloride (PCl₃), Cl₂, and hydrogen chloride (HCl).

In one aspect it has been observed that surface oxides formed with exposure to ambient, for example during the ex situ etching operation, re-form after an aqueous HF clean and prior to transfer to the MOCVD chamber. It has additionally been observed that in situ etching with chlorine based chemistries does not remove pre-existing surface oxide. Although original ambient-exposed surfaces are effectively etched, it has been observed that oxygen contamination is not reduced and remains on the surface. Furthermore, oxygen contamination may be proportional to aluminum content of the exposed surfaces.

In accordance with embodiments an in situ cleaning operation may be performed prior to the in situ etching operation. In an embodiment, a hydrogen plasma clean is performed prior to regrowth of the second cladding layer 112. For example, a hydrogen plasma source can be connected to the MOCVD system at a suitable location such as a load/lock chamber, reaction chamber, or any vacuum portion to not expose the surface to atmosphere prior to regrowth in order to reduce surface oxide prior to regrowth.

In another aspect it has been observed that in situ cleaning with active hydrogen is highly dependent upon aluminum concentration. In accordance with various embodiments described herein the in situ cleaning operation may be performed on surfaces with no aluminum, or low aluminum concentration in order to eliminate surface oxides, and prevent such surface oxide transfer to the regrowth interface. As shown in FIGS. 3B-3C, the in situ etching is performed through a GaInP sacrificial semiconductor layer 111, and low aluminum containing active layer 109 such as (AlₓGa₁₋ₓ)_{0.5}In_{0.5}P, with 0.2≤x.

As shown in FIG. 3C, immediately following the in situ etching operation the second cladding layer 112 can be regrown, followed by regrowth of the bottom contact layer 132 (e.g. p-type contact layer). Each of such layers may be globally regrown, though masking may be utilized if desired to prohibit regrowth over certain areas of the step surface 107, for example to aid in etching of the trenches 140.

The following processing sequence may proceed similarly as FIGS. 1D-1H. As shown in FIG. 3D, trenches 140 may be formed followed by the formation of optional insulation layer 150 and conductive contact 156 as shown in FIG. 3E and sacrificial release layer as shown in FIG. 3F. The patterned structure on the growth substrate 101 can then be bonded to a carrier substrate 180 with an adhesive bonding material to form stabilization layer 170 as shown in FIG. 3G. After bonding to the carrier substrate 180, the growth substrate 101 may be removed utilizing a suitable technique such as laser lift-off, etching. Furthermore, the buffer layer 102 may also be removed to expose the top contact layers 104 to form laterally separate LEDs 175 (micro LEDs) as shown in FIG. 3H.

In an embodiment, an LED 175 (e.g. micro LED) includes a base structure 125 which includes a first cladding layer doped 106 with a first dopant type (e.g. top, n-type cladding layer) and a step surface 107. The base structure 125 may additionally include a top contact layer 104 (e.g. n-type contact layer). As shown, a mesa pillar 120 protrudes from the step surface 107 of the base structure 125 and includes an active layer 109. In the particular embodiment illustrated the active layer 108 is a single layer. Furthermore, the mesa pillar 120 may be formed entirely of the active layer 109, and optionally a portion of the first cladding layer 106. A regrowth structure may be formed around the mesa pillar 120 and along the step surface 107. As shown, a second cladding layer 112 (e.g. p-type cladding layer) can be in direct contact with and span the bottom surface 122 and mesa sidewalls 121 of the mesa pillar 120 as well as the step surface 107 of the base structure 125. Thus, the second cladding layer can wrap underneath the mesa pillar and step surface. Additionally, a bottom contact layer 132 (e.g. p-type contact layer) may be formed directly on the second cladding layer 112 and wrap underneath the second cladding layer 112.

In accordance with the illustrated embodiment the LED 175 sidewalls may be composed of the edge sidewalls 142 that span across the (etched) bottom contact layer 132, second cladding layer 112, the first cladding layer 106, and optional top contact layer 104. The LED sidewalls may additionally be composed of the optional bottom contact layer 132 that wraps underneath the semiconductor passivation layer and the mesa pillar 120.

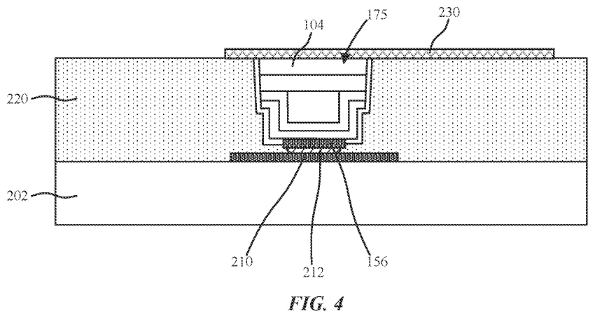

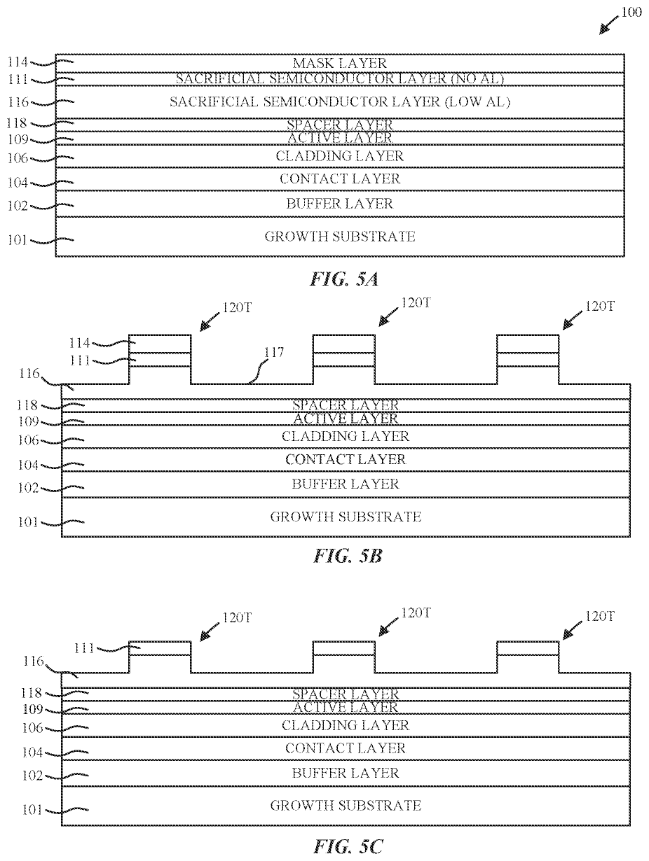

FIG. 4 is a schematic cross-sectional side view illustration of an LED 175 (micro LED) with regrown cladding layer bonded on a display substrate in accordance with an embodiment. Similar to the micro LED array described with regard to FIG. 1H, in accordance with embodiments, the LED 175 array of FIG. 3H can be processed to remove the sacrificial release layer 160, such as with a vapor HF etch process, followed by transfer to a receiving substrate such as display substrate 202.

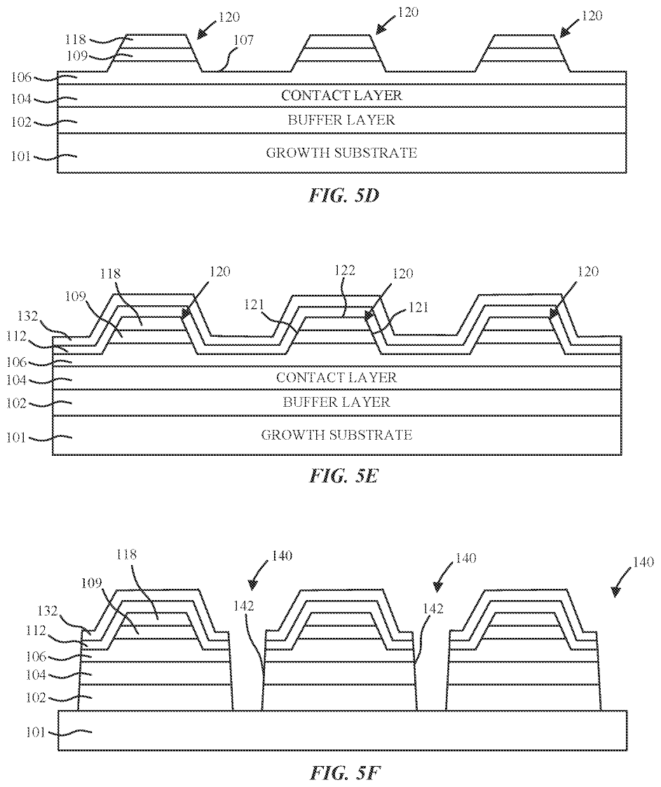

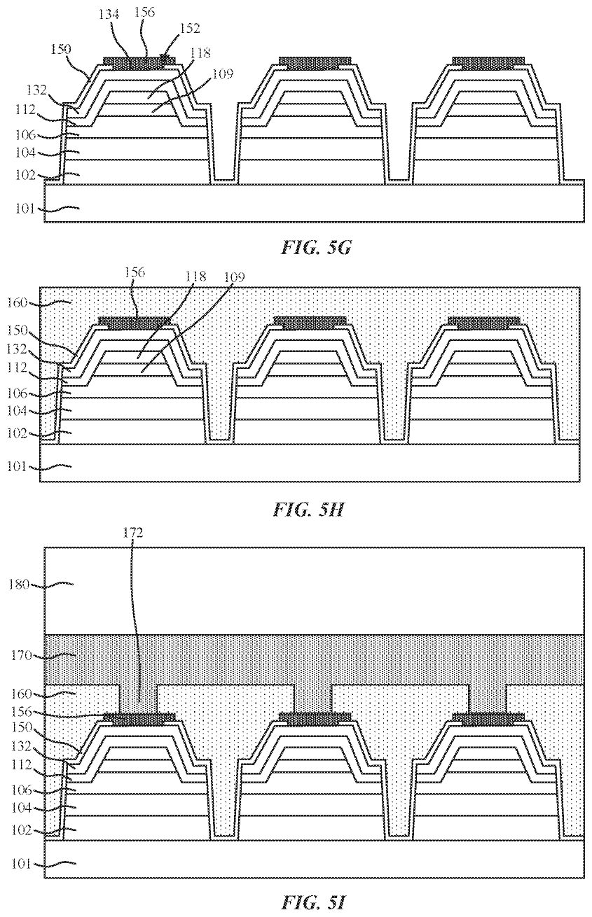

Referring now to FIGS. 5A-5J schematic cross-sectional side view illustrations are provided of a sequence for forming an array of micro LEDs with a regrown cladding layer on a carrier substrate in accordance with an embodiment. It is to be appreciated that the various structures presented in FIGS. 5A-5J may share similar layers and compositions as the layers previously described and illustrated with regard to FIGS. 1A-1H and FIGS. 3A-3H. Accordingly, in the interest of clarity and conciseness, the description of layers and structures with similar arrangements and compositions may not be repeated.

As shown, the process sequence may begin with a bulk LED substrate 100 including a growth substrate 101 (e.g. GaAs), one or more buffer layers 102 (e.g. graded from GaAs to AlGaAs), a top contact layer 104 (e.g. n-type contact layer) such as (AlₓGa₁₋ₓ)_{0.5}In_{0.5}P, with 0.2≤x≤0.8, a first cladding layer 106 (e.g. n-type cladding layer) such as (AlₓGa₁₋ₓ)_{0.5}In_{0.5}P alloys with 0.6≤x≤1.0, in particular AlInP, and an active layer 109 such as (AlₓGa₁₋ₓ)_{0.5}In_{0.5}P, with 0.2≤x. Unlike the active layer 109 of bulk substrate 100 for the process sequence in FIG. 3A, the thickness of the active layer 109 of FIG. 5A is not partially reduced in the final product, which can preserve integrity of the active layer 109 and mitigate potential for defects and oxygen contamination on the active layer 109.

Still referring to FIG. 5A, a spacer layer 118 is formed over the active layer 109. The spacer layer may be 25 nm to 100 nm thick, such as 50 nm thick in an embodiment. In an embodiment, the spacer layer may be formed of the same material and stoichiometric composition as the second cladding layer (e.g. p-type cladding layer) to be subsequently formed. This can facilitate crystal quality for regrowth, though this is not strictly required. The spacer layer 109 may provide various functions, including providing a surface for regrowth, moving the regrowth interface a minimum distance away from the active layer 109, as well as to provide a diffusion barrier for p-dopants to the active layer 109. In an embodiment, the spacer layer 118 is unintentionally doped. Following the formation of the spacer layer 118 a first sacrificial semiconductor layer 116 is formed, such as (AlₓGa₁₋ₓ)_{0.5}In_{0.5}P, with 0.2≤x, followed by a second sacrificial semiconductor layer 111, such as (AlₓGa₁₋ₓ)_{0.5}In_{0.5}P, with x=0, and a mask layer 114 as previously described. In accordance with embodiments, the first sacrificial semiconductor layer 116 has a higher aluminum concentration than the second sacrificial semiconductor layer 111, which may have no aluminum, and consequently a slightly lower etch rate with a chlorine based etch chemistry. Where the second sacrificial semiconductor layer 111 is GaInP, surface oxides may be potentially be more easily removed during cleaning, further mitigating the ability for surface oxides to transfer to the bottom surface 122 of the mesa pillar 120 after the in situ etching sequence.

Referring now to FIGS. 5B-5D, a two-part etching sequence may be performed to form the mesa pillars 120. In accordance with embodiments, the mesa pillar templates 120T can be first formed using an etching technique such as DRIE to etch through the second sacrificial semiconductor layer 111 and into a bulk of the first sacrificial semiconductor layer 116 using a patterned mask layer 114. This etching operation may be formed partially through a thickness of the first sacrificial semiconductor layer 116 as shown in FIG. 5B. This may be followed by stripping the mask layer 114 as shown in FIG. 5C, for example using a vapor hydrofluoric acid (HF) etch or buffered oxide etch (BOE) of aqueous hydrofluoric acid (HF) and ammonium fluoride (NH₄F).

Following the bulk etching operation and cleaning the substrate stack can then be transferred to an MOCVD system for additional etching and regrowth. In an embodiment, the substrate stack is cleaned again in situ within the MOCVD system to remove any additional oxide that could have formed after vapor HF or BOE cleaning. For example, a hydrogen plasma clean can be performed within the MOCVD system at a suitable location such as a load/lock chamber, reaction chamber, or any vacuum portion to not expose the surface to atmosphere prior to regrowth in order to reduce surface oxide prior to regrowth. This optional cleaning operation can then be followed by in situ etching within the MOCVD reaction chamber using a suitable chlorine based etch chemistry such as TBCl, PCl₃, Cl₂, and HCl. As shown in FIG. 5D the in situ etching operation completely removes the second sacrificial semiconductor layer 111 and first sacrificial semiconductor layer 116, and etching continues completely through the spacer layer 118 and active layer 109 to expose the first cladding layer 106 and form mesa pillars 120. Such an etching operation may etch partially through a thickness of the first cladding layer 106.

As shown in FIG. 5E, immediately following the in situ etching operation, a second cladding layer 112 and bottom contact layer 132 may be regrown. Each of such layers may be globally regrown, though masking may be utilized if desired to prohibit regrowth over certain areas of the step surface 107, for example to aid in etching of the trenches 140.

The following processing sequence may proceed similarly as FIGS. 1D-1H. As shown in FIG. 5F, trenches 140 may be formed followed by the formation of optional insulation layer 150 and conductive contact 156 as shown in FIG. 5G and sacrificial release layer 160 as shown in FIG. 5H. The patterned structure on the growth substrate 101 can then be bonded to a carrier substrate 180 with an adhesive bonding material to form stabilization layer 170 as shown in FIG. 5I. After bonding to the carrier substrate 180, the growth substrate 101 may be removed utilizing a suitable technique such as laser lift-off, etching. Furthermore, the buffer layer 102 may also be removed to expose the top contact layers 104 to form laterally separate LEDs 175 (micro LEDs) as shown in FIG. 5J.

In an embodiment, an LED 175 includes a base structure 125 which includes a first cladding layer 106 doped with a first dopant type (e.g. top, n-type cladding layer) and a step surface 107. The base structure 125 may additionally include a top contact layer 104 (e.g. n-type contact layer). As shown, a mesa pillar 120 protrudes from the step surface 107 of the base structure 125 and includes an active layer 109. In the particular embodiment illustrated the active layer 109 is a single layer, and the mesa pillar 120 additionally includes a spacer layer 118 underneath the active layer 109. The spacer layer 118 may be unintentionally doped. As such a bottom surface 122 of the mesa structure pillar 120 is a surface of the spacer layer 118.

The mesa pillar 120 may be formed of the spacer layer 118, the active layer 109, and optionally a portion of the first cladding layer 106. A regrowth structure may be formed around the mesa pillar 120 and along the step surface 107. As shown, a second cladding layer 112 can be in direct contact with and span the bottom surface 122 and mesa sidewalls 121 of the mesa pillar 120 as well as the step surface 107 of the base structure 125. Thus, the second cladding layer 112 can wrap underneath the mesa pillar and step surface. Additionally, a bottom contact layer 132 (e.g. p-type contact layer) may be formed directly on the second cladding layer 112 (e.g. p-type cladding layer) and wrap underneath the second cladding layer 112.

In accordance with the illustrated embodiment the LED 175 sidewalls may be composed of the edge sidewalls 142 that span across the (etched) bottom contact layer 132, second cladding layer 112, the first cladding layer 106, and optional top contact layer 104. The LED sidewalls may additionally be composed of the optional bottom contact layer 132 that wraps underneath the second cladding layer 112 and the mesa pillar 120.

The LED 175 of FIG. 5J, as well as the LED 175 of FIG. 3H, differ from the LED 175 of FIG. 1H in that the mesa pillar 120 does not include a layer doped with the second dopant type (e.g. p-type). As such, rather than forming a semiconductor passivation layer around both p/n junction layers of a diode structure the second junction layer (or cladding layer) is instead wrapped around the active layer. Such a configuration can facilitate a reduction in LED size (width), and also allow a processing sequence that limits exposure of aluminum containing layers to ambient, and hence potential for oxidation near the active layer edges. In particular, in the processing sequence of FIGS. 3A-3H the bottom surface 122 and mesa sidewalls 121 of the mesa pillar 120 correspond to a bottom surface and sidewalls of the active layer 109 that is formed with an in situ etch and regrowth of the second cladding layer 112. In the processing sequence of FIGS. 5A-5J the bottom surface 122 of the mesa pillar 120 corresponds to a surface of a spacer layer 118 that is only first exposed during an in situ etch and regrowth of the second cladding layer 112. In this configuration any defects due to etching can be set back from the active layer 109 some to preserve integrity of the active layer 109.

In a specific embodiment the first cladding layer 106 includes n-doped AlInP, the active layer 109 includes AlGalnP, the second cladding layer 112 includes p-doped AlInP, and the spacer layer 118 includes AlInP and is unintentionally doped. Since the regrowth interface for the second cladding layer 112 is compositionally and lattice-matched with the spacer layer 118 and first cladding layer 106 it would be expected that the interface would not be visible. In accordance with embodiments, a thin interface may be visible with a transmission electron microscopy (TEM) cross-section. Compositional analysis using secondary ion mass spectroscopy (SIMS) or energy dispersive x-ray (EDX) spectroscopy in accordance reveals that this thin interface (less than 10 nm thick) is indium-deficient AlInP, where the alloy composition has less indium than the lattice-matched value. This deviation from the stoichiometric bulk composition has been observed to be the result of the chlorine based in situ etching performed in the MOCVD reactor prior to regrowth. Specifically, a fingerprint of chlorine based etching in accordance with embodiments is that the regrowth interface after in situ etching can be observed as not being stoichiometric. This may be due to etching byproducts being carried away at different rates. This non-stoichiometric regrowth interface has been observed to leave a less than 10 nm thick surface region that is aluminum-rich (or equivalently indium-deficient). Specifically, the increased aluminum concentration may be at least 1-2 atomic percent of the in situ etched layers (first cladding layer 106, active layer 109, spacer layer 118), and decreased indium concentration may be at least 1-2 atomic percent of the in situ etched layers. This thin interface may extend less than 10 nm into the in situ etched layers, such as 2-5 nm, for example. In an embodiment, a first 2-5 nm of the spacer layer 118 adjacent the bottom surface 122 of the mesa pillar 120 includes an increased aluminum concentration and decreased indium concentration relative to a bulk composition of the spacer layer 118. For example, the increased aluminum concentration is at least 1-2 atomic percent relative to the bulk composition of the spacer layer 118, and the decreased indium concentration is at least 1-2 atomic percent relative to the bulk composition of the spacer layer 118. In an embodiment, the spacer layer is less than 100 nm thick.

In an embodiment, the base structure is characterized by a maximum width of 1-100 μm, such as 1-10 μm. In an embodiment, the mesa pillar is characterized by a maximum width of 0.1-5 μm.

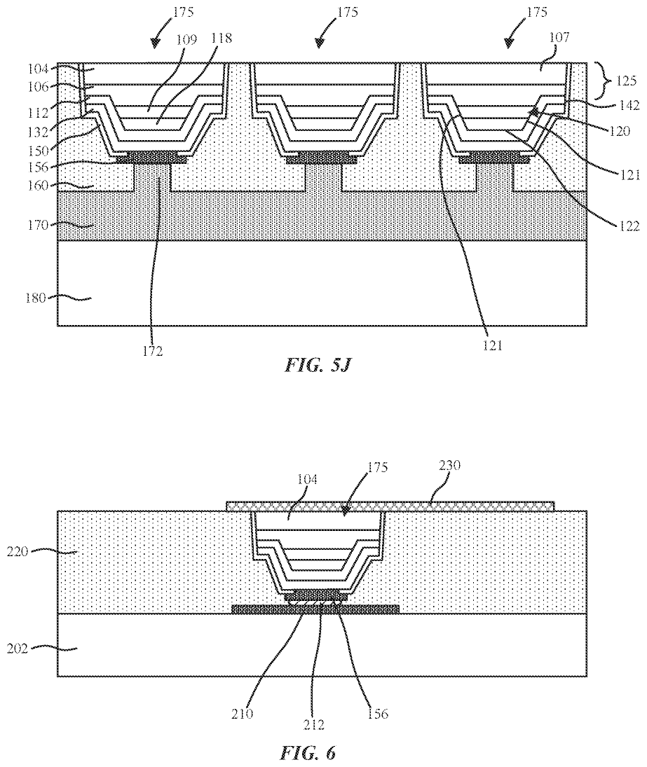

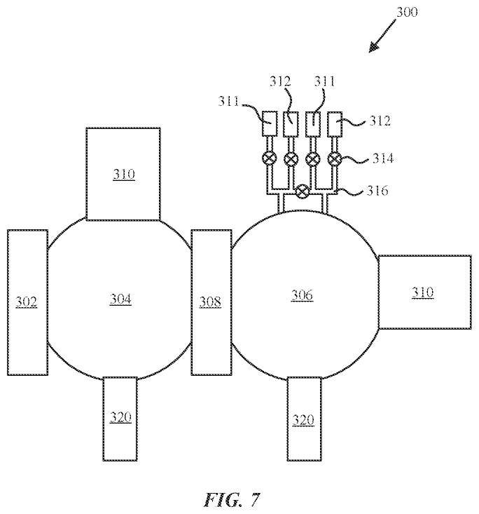

FIG. 6 is a schematic cross-sectional side view illustration of an LED 175 (micro LED) with regrown cladding layer bonded on a display substrate in accordance with an embodiment. Similar to the micro LED array described with regard to FIG. 1H, in accordance with embodiments, the LED 175 array of FIG. 5J can be processed to remove the sacrificial release layer 160, such as with a vapor HF etch process, followed by transfer to a receiving substrate such as display substrate 202.

Referring now to FIG. 7, a schematic plan view is provided of an MOCVD system 300 that may be utilized in accordance with embodiments. As shown the MOCVD system 300 can include an entry door 302 to a load lock chamber 304, which can be connected to a reactor chamber 306 through shutter 308. Pumps 310 can be connected to the load lock chamber 304 and the reaction chamber 306 to control vacuum pressure. A plurality of precursor supplies 311 and carrier gas sources 312 can be connected to the reaction chamber 306 using a suitable assembly is distribution lines 316 and valves 314, such as mass flow controllers. The arrangement of precursor supplies and carrier gas sources 312 can be arranged to provide in situ etching and regrowth. In accordance with embodiments a hydrogen plasma source 320 can be connected to either or both of the load lock chamber 304 or reaction chamber 306, for example, to perform in situ cleaning.

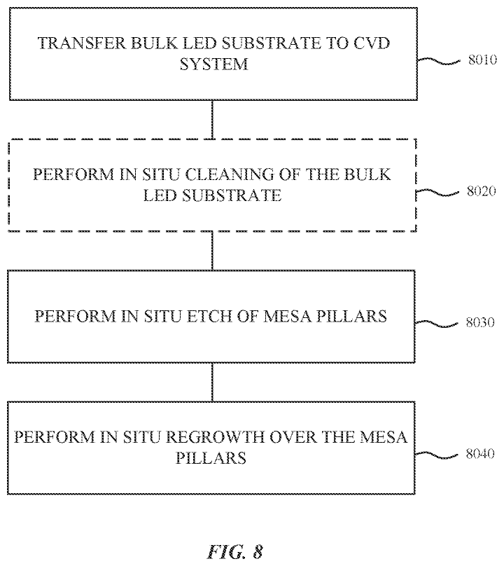

A flow chart is provided in FIG. 8 for an in situ sequence of operations during the formation of an array of micro LEDs in accordance with an embodiment. In particular, the sequence may be performed within the MOCVD system of FIG. 7 in conjunction with the process flows of FIGS. 1A-1H, FIGS. 3A-3H, and FIGS. 5A-5J previously described. In an embodiment, the method of forming an array of LEDs (e.g. micro LEDs) includes transferring a bulk LED substrate to a chemical vapor deposition (CVD) system, such as an MOCVD system 300, at operation 8010. An in situ cleaning operation can then optionally be performed on the bulk LED substrate at operation 8020. For example, this may be achieved by exposing the bulk LED substrate to active hydrogen. In an embodiment, this can be achieved with a hydrogen plasma, such as with a hydrogen plasma source 320 under vacuum either within the reaction chamber 306 of the MOCVD system 300 or within another location that is under vacuum, such as load lock chamber 304.

An array of mesa pillars is then etched through an active layer of the bulk LED substrate at operation 8030. For example, this may be performed in the reaction chamber 306 using a chlorine based etch chemistry. This is followed by in in situ regrowth of one or more semiconductor layers directly on the array of mesa pillars at operation 8040. In accordance with embodiments, the bulk LED substrate is not exposed to ambient atmosphere during the in situ processing sequence of operations 8020-8040.

Following the in situ processing sequence, the bulk LED substrate may be additionally processed as previously described with the process flows of FIGS. 1A-1H, FIGS. 3A-3H, and FIGS. 5A-5J. For example, this may include subsequently transferring the bulk LED substrate to a dry etching system, and etching a pattern of trenches through an underlying cladding layer to define an array of LEDs. In a particular embodiment, each LED includes a single mesa pillar, and a maximum width of the underlying cladding layer for each LED is 0.1 μm to 20 μm.

In utilizing the various aspects of the embodiments, it would become apparent to one skilled in the art that combinations or variations of the above embodiments are possible for forming micro LEDs with regrown layers. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A light emitting diode comprising:
a base structure including:
a first cladding layer doped with a first dopant type; and
a step surface;
a mesa pillar protruding from the step surface of base structure, the mesa pillar including an active layer; and
a second cladding layer in direct contact with and spanning a bottom surface and mesa sidewalls of the mesa pillar and the step surface of the base structure, wherein the second cladding layer is doped with a second dopant type opposite the first dopant type.

2. The light emitting diode of claim 1, further comprising a bottom contact layer directly on the second cladding layer.

3. The light emitting diode of claim 2, further comprising edge sidewalls spanning across the bottom contact layer, the second cladding layer and the first cladding layer.

4. The light emitting diode of claim 1, wherein the mesa pillar protrudes from the first cladding layer.

5. The light emitting diode of claim 1, wherein the mesa pillar does not include a layer doped with the second dopant type.

6. The light emitting diode of claim 5, wherein the first cladding layer comprises n-doped AlInP.

7. The light emitting diode of claim 6, wherein the active layer comprises AlGaInP.

8. The light emitting diode of claim 7, wherein the second cladding layer comprises p-doped AlInP.

9. The light emitting diode of claim 8, wherein the mesa pillar includes a spacer layer underneath the active layer, wherein the bottom surface of the mesa pillar is a surface of the spacer layer.

10. The light emitting diode of claim 9, wherein the spacer layer is an unintentionally doped spacer layer.

11. The light emitting diode of claim 9, wherein the spacer layer comprises AlInP.

12. The light emitting diode of claim 9, wherein a first 2-5 nm of the spacer layer adjacent the bottom surface of the pillar structure includes an increased aluminum concentration and decreased indium concentration relative to a bulk composition of the spacer layer.

13. The light emitting diode of claim 12, wherein the increased aluminum concentration is at least 1-2 atomic percent relative to the bulk composition of the spacer layer.

14. The light emitting diode of claim 12, wherein the decreased indium concentration is at least 1-2 atomic percent relative to the bulk composition of the spacer layer.

15. The light emitting diode of claim 12, wherein the spacer layer is less than 100 nm thick.

16. The light emitting diode of claim 9, wherein the base structure is characterized by a maximum width of 1-100 μm.

17. The light emitting diode of claim 9, wherein the base structure is characterized by a maximum width of 1-10 μm.

18. The light emitting diode of claim 9, wherein the mesa pillar is characterized by a maximum width of 0.1-5 μm.

19. A method of forming an array of light emitting diodes (LEDs) comprising:
transferring a bulk LED substrate to a CVD system;
etching an array of mesa pillars through an active layer of the bulk LED substrate;
regrowing a semiconductor layer directly on the array of mesa pillars;
wherein the bulk LED substrate is not exposed to ambient atmosphere between etching the mesa pillar and regrowing the second cladding layer.

20. The method of claim 19, wherein the etching is performed with a chlorine based chemistry.

21. The method of claim 19, further comprising cleaning the bulk LED substrate after transferring the bulk LED substrate to the CVD system, and prior to etching the array of mesa pillars.

22. The method of claim 21, wherein the cleaning comprises exposure of the bulk LED substrate to active hydrogen.

23. The method of claim 22, wherein the cleaning is performed in a reactor chamber of the CVD system.

24. The method of claim 22, wherein the cleaning is performed under vacuum outside of a reactor chamber of the CVD system without exposing the bulk LED substrate to ambient atmosphere.

25. The method of claim 19, wherein each mesa pillar of the array of mesa pillars includes an unintentionally doped spacer layer over the active layer.

26. The method of claim 19, further comprising partially etching an array of mesa pillar templates through the active layer in a first etching operation prior to transferring the bulk LED substrate to the CVD system.

27. The method of claim 19, further comprising etching the array of mesa pillar templates partially through a sacrificial semiconductor layer in a first etching operation prior to transferring the bulk LED substrate to the CVD system.

28. The method of claim 19, further comprising transferring the bulk LED substrate to a dry etching system after regrowing the semiconductor layer, and etching a pattern of trenches through an underlying cladding layer to define an array of LEDs.

29. The method of claim 19, wherein each LED includes a single mesa pillar, and a maximum width of the underlying cladding layer for each LED is 0.1 μm to 20 μm.
